(19) United States
(12) Patent Application Publication
(10) Pub. No.: US 2012/0090668 A1
(43) Pub. Date: Apr. 19, 2012

(54) Photovoltaic Module and Method for the Production Thereof

(75) Inventor: Alexander Pfeuffer, Bielefeld (DE)

(73) Assignee: Malibu GmbH & Co. KG, Bielefeld (DE)

(21) Appl. No.: 13/380,276

(22) PCT Filed: Jun. 17, 2010
(86) PCT No.: PCT/EP2010/058555

§ 371 Date: Dec. 22, 2011

(30) Foreign Application Priority Data
Jun. 24, 2009 (DE) 102009026026.9

(51) Int. Cl. H01L 31/048; H01L 31/18

(52) U.S. Cl. 136/251; 438/57; 257/E31.119

(57) ABSTRACT

A photovoltaic module, particularly a thin-film photovoltaic module, includes at least one carrier panel preferably implemented as a glass panel, one or more coatings applied to the carrier panel for generating electrical current, at least one or more electrically conductive contacts, at least one cover coating for covering at least one partial region of the carrier panel with the coatings generating electricity, the electrically conductive contacts and optionally a glass cover panel. The cover coating is particularly implemented as a melted coating, at least one bulk granular granulate being used for the production thereof.

### BACKGROUND AND SUMMARY OF THE INVENTION

The invention relates to a photovoltaic module and a method for the production thereof.

Photovoltaic modules and methods for their production are known in numerous variants.

Adhesive films made of ethyl vinyl acetate (EVA) are usually used in the solar industry for producing so-called laminates with crystalline silicon solar cells. The solar cells are usually embedded between two EVA films.

Front glass and a weather-proof back film protect the cells from mechanical loads and the penetration of humidity.

The lamination process occurs by a vacuum laminator. The composite is heated in this device by a heating plate and is vented by vacuum pumps. After the film is molten down, a mechanical pressure is built up via a membrane and is held until the EVA polymer film has cross-linked sufficiently.

Methods which are based on the production of laminated safety glass panels are employed for the encapsulation of thin-film photovoltaic modules. It is therefore known from the area of glass production to produce laminated safety glass panels in which a hot-melt adhesive film which is made from extruded polyvinyl butyral (PVB) and which is processed with a suitable method joins two glass panels. A two-stage lamination process is usually applied for this purpose:

Venting of the composite in a roller furnace or in a vacuum bag.

Dissolving the residual air in the PVB film in the autoclave.

Current-generating or current-producing layers and optionally contacts and the like are applied at first to a carrier panel preferably arranged a glass panel in the encapsulation of the thin-film photovoltaic modules. An uncoated PVB film (e.g. with a height of 1.14 mm) is then applied to this arrangement, which is also used for being connected with a covering glass pane.

Either a two-stage roller furnace/autoclave process or a single-process in the vacuum laminator can be used for the joining process.

The production of bubble-free laminates is complicated by metallic contact ribbons that increase the layer height and depressions in the glass body (e.g. arising by removal of edge coating) (different topology).

It is further disadvantageous that it is often necessary to cut off the protruding PVB film after the production of the laminate by hand.

It is further disadvantageous in the production of thin-film solar modules with PVB films that glass fractures can occur as a result of the topology (different layer heights) of the current-generating layers and that a relatively large amount of the PVB material needs to be used because the film thicknesses cannot be minimized at will. Furthermore, it is desirable that the degree of automation in the production of photovoltaic module is increased.

It is therefore the object of the invention to remedy at least one or several of the disadvantages as described above.

This object is achieved by the invention with respect to the photovoltaic module especially a thin-film photovoltaic module, which comprises at least the following: a carrier panel preferably implemented as a glass panel; one or more coatings applied to the carrier panel for generating electrical current; at least one or more electrically conductive contacts; at least one cover coating for covering at least one partial region of the carrier panel or the entire carrier panel with the coating generating electricity, the electrically conductive contacts, and optionally a cover panel preferably implemented as a glass panel; wherein the cover coating is especially implemented as a hot-melt coating, with at least one bulk granular granulate being used for the production thereof. The granular granulate may be pourable.

The object is further achieved with respect to the method for producing the photovoltaic module especially a thin-film photovoltaic module, comprising the following steps: a) applying one or more coatings for generating electrical current and at least one or several electrically conductive contacts to a carrier panel preferably implemented as a glass panel; b) applying at least one cover coating for covering at least a partial area of the carrier panel or the entire carrier panel with the current-generating coatings and the electrically conductive contacts to the arrangement produced in step a); wherein the cover coating of step b) is especially arranged as a hot-melt coating by using at least one bulk granular granulate. The granular granulate may be pourable.

Preferably, the granulate is applied in such a way to the arrangement made of the carrier panel or the entire carrier panel with current-generating coatings and the electrically conductive contacts that the differences in the height of the coatings and contacts arranged on the carrier panel and the carrier panel which is optionally not covered in part is compensated by the granulate.

The granulate is especially preferably a polyvinyl butyral granulate. The use of the granulate provides a minimization in the material, leading to low production costs.

The production costs can be reduced even further if the PVB granulate consists of recycled PVB material.

The step c) preferably has the following partial steps for producing a hot-melt coating:

The application of the granulate to the arrangement produced in step a).

Melting of the granulate, especially in a lamination process, for forming a continuous, non-grainy cover coating.

It has proven to be especially advantageous for the arrangement of a hot-melt coating if the grain size of the granulate is smaller than 2.5 mm, preferably smaller than 0.5 mm and more preferably smaller than 0.25 mm.

The size of the granulate or the grain size of the granulate is based among other things on the method for application. The optimal grain size can be determined with the simplest of tests.

The application of the granulate in form of powder is possible (similar to the application of paint). It is also possible to use granulates of a larger grain size, right up to plate-like granulate particles of a size of up to some millimeters which can simply be sprinkled.

Preferably, the granulate is used of a size of a few tenths of millimeters. Granulate chips were used in the test which had a diameter of approximately 5 mm and a height of approximately 1.14 mm. As a result, the topology of the thin-film module can be filled easily or leveled appropriately. Excess PVB granulate can be removed or sucked off again.

According to one variant of the invention, the granulate is applied to the arrangement of step a) in such a way that the differences in height of the coatings and contacts arranged on the carrier panel and the areas on the carrier panel which are optionally not covered can be leveled by the granulate. A flat surface is formed thereby, to which a glass panel can be applied (e.g. glued).

In accordance with another variant of the invention, the granulate is applied at a different height to the arrangement of the step a).

The PVB granulate can advantageously be produced by recycled PVB (windscreens, laminated glass panes), which is cheap and easily available.

The production process on the basis of a granulate will also be referred to below as lamination process. This lamination process requires sufficient evacuation (e.g. in the vacuum laminator) and melting down of the granulate. A vacuum laminator can be used for this purpose for example. An excess portion of the film cannot be formed in this method, so that manual severing is not required. The degree of automation can further be increased thereby.

It would also be possible to use a heating station with upstream evacuation.

The method in accordance with the invention allows according to one variant to level a module topology which is basically unfavorable for applying a coating.

The likelihood of glass fracture during the lamination process is reduced thereby and the input of material is reduced. The cost of materials can be reduced by using the PVB granulate.

As a result of influencing the application of the granulate in a purposeful way, the edge-deleted zones and the contact strips can be provided with additional PVB material, whereas the actual module area, which forms the essential proportion of the area, is supplied with less PVB.

Moreover, successions of coatings of uncolored and colored PVB granulate can be realized in a simple way. This is especially an option for the production of a-Si/μc-Si tandem cells which require a high degree of reflectivity of up to 1,100 nm.

In addition, the coloring can be varied via the module area. This is advantageous if no colored PVB is desired in the edge-deleted zones which would distort the optics of the module.

### BRIEF DESCRIPTION OF THE DRAWINGS

Embodiments of state of the art and the invention will be described below in closer detail by reference to the drawings, wherein:

FIG. 1 shows a top view of a thin-film solar module;

FIGS. 2 to 4 show partial sectional views along the planes A-A, B-B, C-C of FIG. 1;

FIGS. 5 to 7 show arrangements analogous to FIG. 2 with a film applied thereto;

FIGS. 8 to 10 show further arrangements analogous to FIG. 2 with the granulate applied thereto, and

FIGS. 11 to 13 show further arrangements analogous to FIG. 2 of a glass panel covered with a granulate, current-generating layers and electrical contacts/contact strips.

### DETAILED DESCRIPTION OF THE DRAWINGS

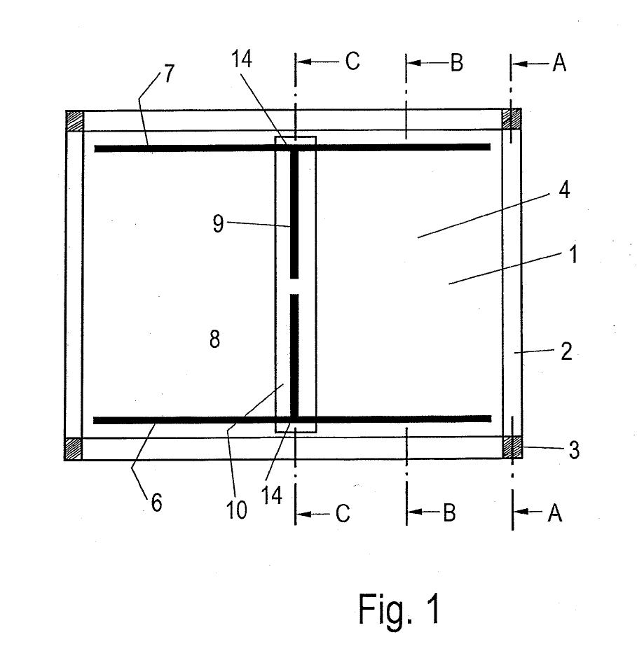

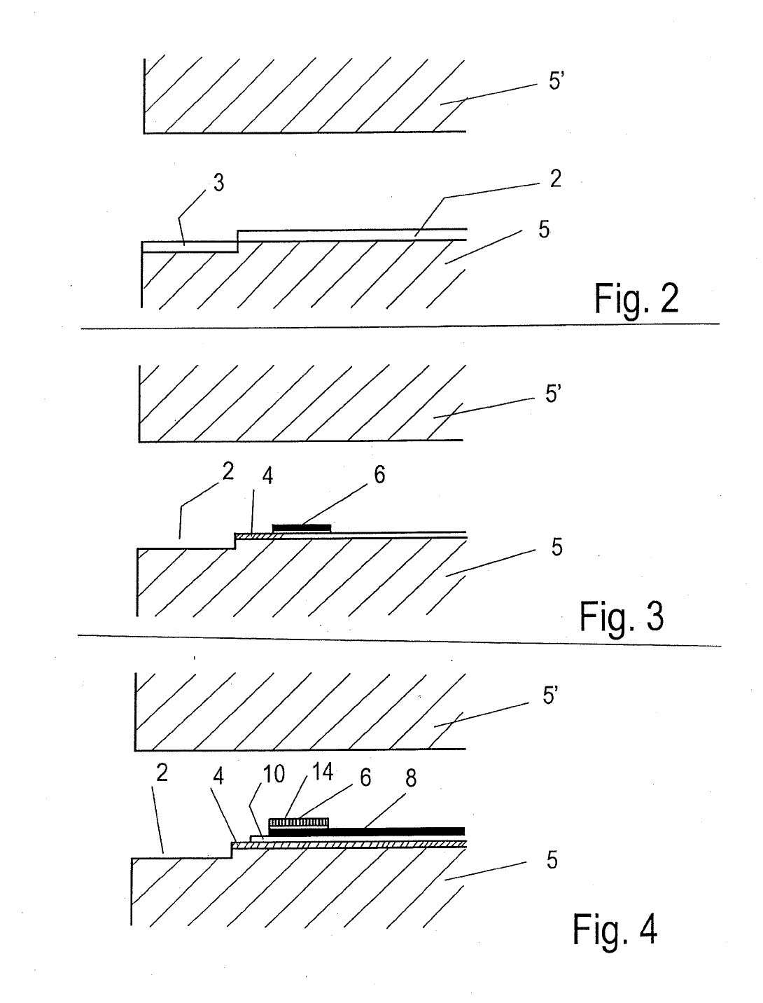

FIG. 1 shows a thin-film solar module 1 in a top view. The thin-film solar module 1 substantially consists of a glass panel 5, to which one or more current-generating coatings 4, (see the side view of FIG. 2) are applied.

This coating or these coatings which generate electricity or electrical power and an edge strip of the glass need to be removed in the edge region of the glass panel again, so that the electrically conductive layer can be encapsulated securely.

The removal of the coating in the edge zone can have a depth of 25 μm for example. In the edge zone corners 3, in which twice the amount of the coating is removed, the removal depth can also be 50 μm for example.

Lateral contact strips 6 and 7 are applied to the coatings 4 (soldered, glued), which are arranged on the plus and minus side for collecting the current.

So-called transverse contacts 8 and 9 are provided for conducting through or passing on the current.

In order to prevent short-circuit, the transverse contacts (contact strips 8 and 9) are arranged on an insulation film 10.

In the crossing regions 12 of the lateral and transverse contacts 6 and 8 they will rise up especially high, so that a total build height of 250 μm can be obtained for example.

FIGS. 2 to 4 show the different topology of a thin-film solar module with its maximum values in a sectional view, as described in connection with FIG. 1.

For example, it can occur that the edge zone 2 has a height of 25 μm, the edge zone corner has a height 50 μm perpendicular to the panel plane, the electrically conductive coating has a height of 1 μm, the lateral contact a height of 100 μm, the transverse contact the height of 100 μm, the insulation film a height of 50 μm, and the PVB film a height of 1.14 mm.

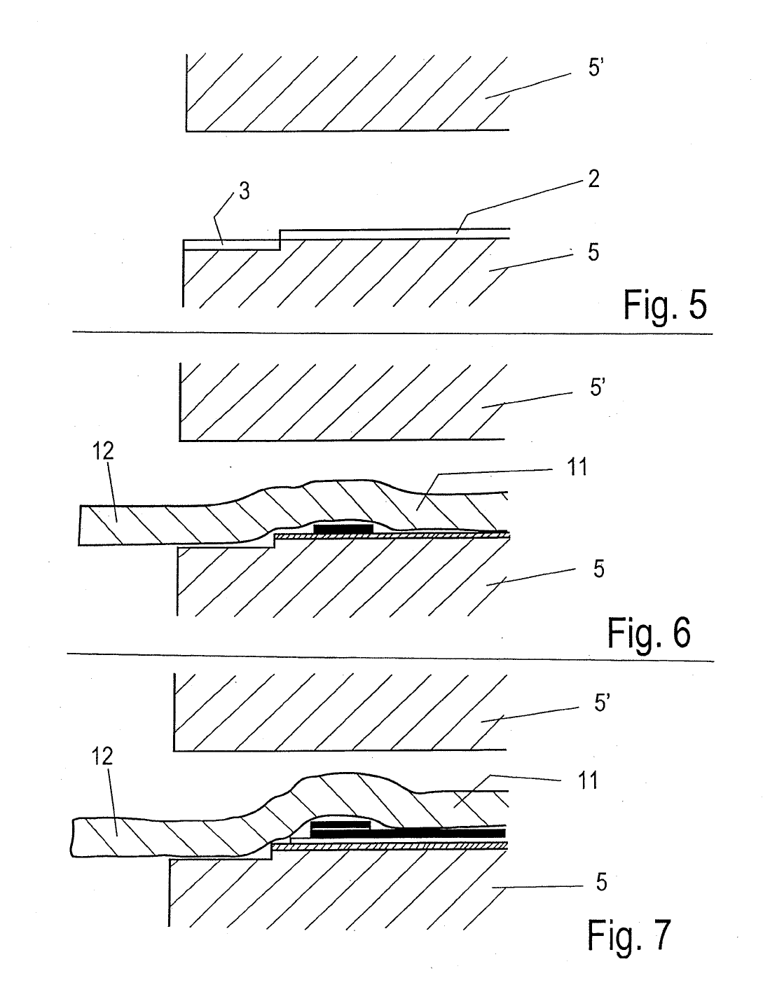

FIGS. 5 to 7 show a lateral view as in FIGS. 2 to 4, with an applied PVB film 11 according to the state of the art.

The illustration, and especially the heights, are illustrated in a highly simplified way and do not correspond to the actual dimensions.

The size of the PVB film area is larger in the production of the thin-film solar modules according to the state of the art than the area of the glass panel, so that the protruding film (excess film portion 15 in FIG. 3) needs to be severed in the edge region.

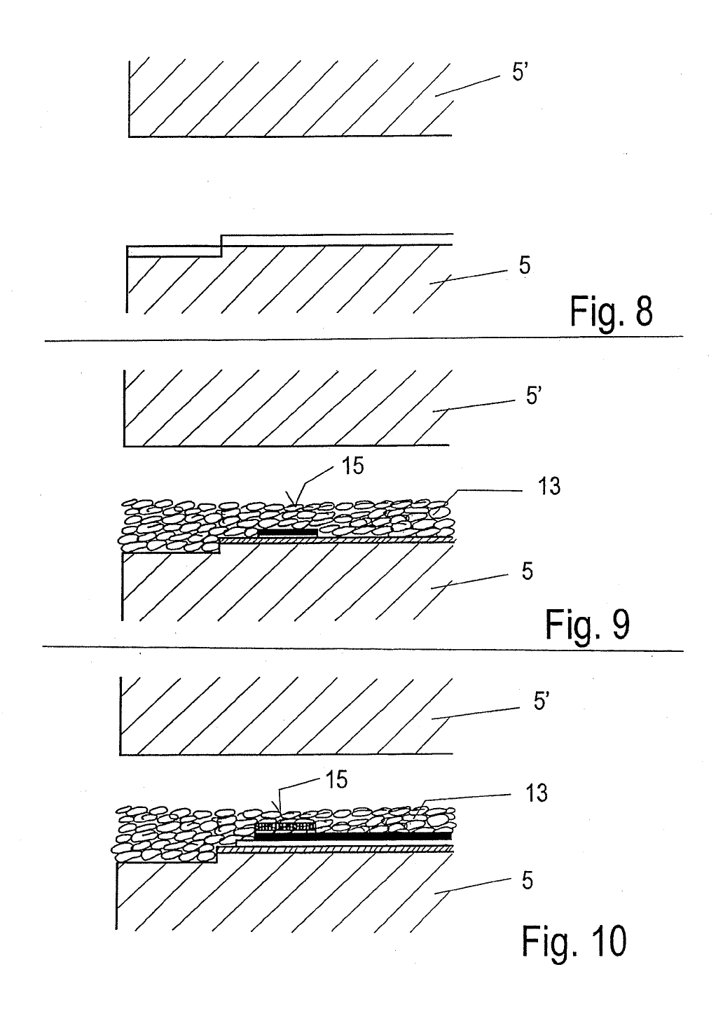

FIGS. 8 to 10 show arrangements in accordance with the invention, with a PVB granulate 13 being used for forming a hot-melt coating instead of the PVB film 11. The drawing shows the state in which the PVB granulate is applied to the arrangement consisting of the glass panel 5, the coatings 4 and the contacts 6, 8. A flat surface 15 can be produced with the PVB granulate on the upper side (FIGS. 9, 10). It can be seen that all heights and depths of the thin-film solar module can be leveled.

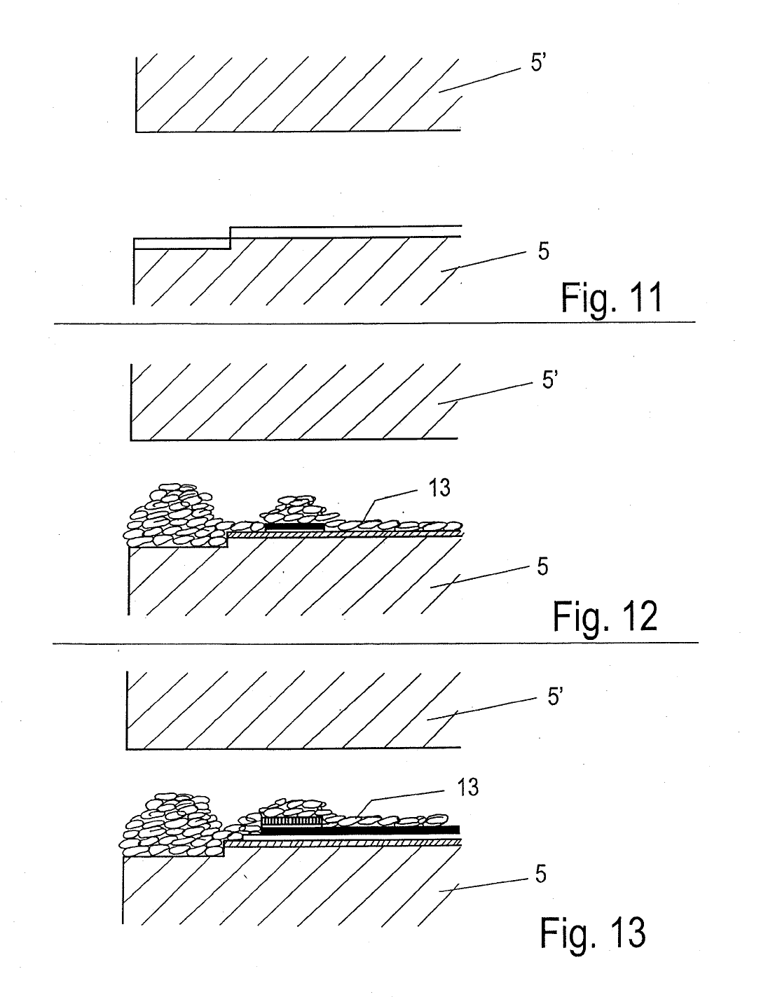

FIGS. 11 to 13 show an advantageous alternative preferred embodiment, in which the topology is not (only) leveled in the critical areas, especially in the edge zones 2, but in which a relatively large additional amount of PVB granulate 13 is accumulated in the critical regions. The likelihood of glass breakage is thereby considerably reduced and the quantity of PVB granulate to be used can be reduced considerably because the height of the PVB coating can be reduced to a minimum, especially in the portions with the large areas.

Potential methods for applying the PVB granulate 13 are top blowing or spraying of PVB granulate or sprinkling of the PVB granulate for example.

The term of granulate shall not be considered in a narrow way. It shall be understood to be a grainy, pourable and non-flowable or non-film-like material.

The PVB granulate can form a PVB powder or PVB platelets or the like.

Smoothing of the PVB granulate 13 is also possible. The granulate 13 can also be supplied to a carrier material (e.g. a fluid which evaporates after application).

Before or after melting down the granulate 13 into a coating, a glass panel can be applied to this arrangement (directly or optionally with an adhesive or lamination process).

It is also possible to chemically and/or physically pre-treat the bottom carrier panel, preferably the glass panel 5, in a suitable manner in order to support the accumulation of the granulate. For example, there can be static charging of the glass panel surface.

### LIST OF REFERENCE NUMERALS

Thin-film solar module 1
Edge zone 2
Edge zone corner 3
Electrically conductive coatings 4
Glass (carrier panel, cover panel) 5
Lateral contact 6
Lateral contact 7
Transverse contact 8
Transverse contact 9
Insulation film 10
PVB film 11
Crossing areas 12
PVB granulate 13
Crossing area 14
Flat area 15

1.-17. (canceled)

18. A photovoltaic module, comprising:
a carrier panel implemented as a glass panel;
one or more coatings applied to the carrier panel for generating electrical current;
at least one or more electrically conductive contacts;
at least one cover coating for covering at least one partial region of the carrier panel with the coating generating electricity and the electrically conductive contacts;
wherein the cover coating is a hot-melt coating, with at least one bulk granular granulate being used for the production thereof.

19. The photovoltaic module according to claim 18, wherein the granulate is applied to an arrangement made of the carrier panel with the current-generating coatings and the electrically conductive contacts such that differences in heights of the coatings and the contacts arranged on the carrier panel are leveled by the granulate.

20. The photovoltaic module according to claim 18, wherein the granulate is a polyvinyl butyral granulate (“PVB granulate”).

21. The photovoltaic module according to claim 20, wherein the PVB granulate comprises recycled PVB material.

22. The photovoltaic module according to claim 18, wherein a grain size of the granulate is less than 2.5 mm.

23. The photovoltaic module according to claim 18, wherein the grain size of the granulate is less than 0.5 mm.

24. The photovoltaic module according to claim 18, wherein the grain size of the granulate is less than 0.25 mm.

25. The photovoltaic module according to claim 18, wherein the photovoltaic module is a thin-film photovoltaic module, and further wherein the cover coating covers the entire carrier panel and a cover panel implemented as a glass panel.

26. A method for producing a photovoltaic module, the method comprising the steps of:
a.) applying one or more coatings for generating electrical current and at least one or several electrically conductive contacts to a carrier panel implemented as a glass panel to produce an arrangement;
b.) applying at least one cover coating for covering at least a partial area of the carrier panel or the entire carrier panel with the current-generating coatings and the electrically conductive contacts to the arrangement produced in step a); and
c.) wherein the cover coating of step b) is arranged as a hot-melt coating by using at least one bulk granular granulate.

27. The method according to claim 26, wherein the step c) comprises the partial steps of:
i) application of the granulate to the arrangement produced in step a);
ii) melting of the granulate for forming a continuous, non-grainy cover coating.

28. The method according to claim 27, wherein the granulate is applied to the arrangement of step a) such that differences in heights of the coatings and contacts implemented on the carrier panel are leveled by the granulate.

29. The method according to claim 27, wherein the granulate is applied in different heights to the arrangement of step a).

30. The method according to claim 26, wherein the granulate is a polyvinyl butyral granulate.

31. The method according to claim 26, wherein the granulate is applied in a spraying process.

32. The method according to claim 26, wherein the granulate is applied by top blowing.

33. The method according to claim 26, wherein the granulate is applied by a pouring process.

34. The method according to claim 26, wherein the granulate is applied with a carrier material.

35. The method according to claim 26, wherein at least two coatings are applied in step c), of which at least one coating is formed by an uncolored PVB granulate and at least one coating of a colored one.

36. The method according to claim 26, wherein in step c), the granulate is applied to zones of increased likelihood of glass breakage with a coating height which is higher than in other areas of the coating.

37. The method according to claim 36, wherein the zones of increased likelihood of glass breakage comprise contacts or edge regions.

38. The method according to claim 35, wherein the coloring is varied over the module area in step c).
